(19) United States
(12) Patent Application Publication
(10) Pub. No.: US 2012/0104520 A1
(43) Pub. Date: May 3, 2012

(54) MEMS SENSOR

(75) Inventors: Yoshitaka UTO, Niigata-ken (JP); Kiyoshi KOBAYASHI, Niigata-ken (JP); Toshihiro KOBAYASHI, Niigata-ken (JP); Toru TAKAHASHI, Niigata-ken (JP); Jun SUZUKI, Niigata-ken (JP); Katsuya KIKUIRI, Niigata-ken (JP)

(73) Assignee: ALPS ELECTRIC CO., LTD., Tokyo (JP)

(21) Appl. No.: 13/347,483

(22) Filed: Jan. 10, 2012

Related U.S. Application Data
(63) Continuation of application No. PCT/JP2010/062425, filed on Jul. 23, 2010.

(30) Foreign Application Priority Data
Aug. 7, 2009 (JP) 2009-184977

(51) Int. Cl. H01L 29/84

(52) U.S. Cl. 257/417; 257/E29.324

(57) ABSTRACT

An MEMS sensor includes: a functional layer having a sensor section; a wiring substrate disposed facing the functional layer and having a conduction pathway for the sensor section; a first metal layer provided on the surface of the sensor section which faces the wiring substrate; and a second metal layer provided on the surface of the wiring substrate which faces the sensor section, wherein the first and second metal layers are joined to each other, a space is formed between a movable portion of the sensor section and the wiring substrate, and a stopper which is composed of a third metal layer being the same film as the first metal layer formed on the functional layer side and a contact portion formed on the wiring substrate side which come into contact with each other is formed between the functional layer and the wiring substrate.

### CLAIM OF PRIORITY

This application is a Continuation of International Application No. PCT/JP2010/062425 filed on Jul. 23, 2010, which claims benefit of Japanese Patent Application No. 2009-184977 filed on Aug. 7, 2009. The entire contents of each application noted above are hereby incorporated by reference.

### BACKGROUND OF THE INVENTION

1. Field of the Invention

The present invention relates to an MEMS sensor that is composed of a first member and a second member which are disposed to face each other.

2. Description of the Related Art

FIG. 6A is a fragmentary longitudinal cross-sectional view schematically showing an MEMS sensor 1 in the related art, and FIG. 6B is a fragmentary enlarged longitudinal cross-sectional view enlarging and showing a portion of FIG. 6A.

The MEMS sensor 1 includes a wiring substrate 2 and a functional layer 3. The functional layer 3 is formed of silicon. Further, the wiring substrate 2 includes a flat plate-like silicon base material 14, an insulating layer 4 formed on an inner surface 14a of the silicon base material 14, and a wiring portion (not show) formed on the insulating layer 4. Then, the wiring portion is led to an electrode pad which is exposed to the outside.

As shown in FIG. 6A, a plurality of second metal layers 15 is formed on a surface 4a of the insulating layer 4 by sputtering or the like.

As shown in FIG. 6A, the functional layer 3 is configured to include a sensor section 5 and a separating layer 6 provided being separated from the sensor section 5. Although it is not shown in the drawing, the sensor section 5 and the separating layer 6 are fixedly supported on a support substrate provided on the opposite side to the surface side facing the wiring substrate 2. The sensor section 5 is configured to include a movable portion 7, an anchor portion 8 which is connected to the movable portion 7, and a spring portion 12 which is interposed between the movable portion 7 and the anchor portion 8. For example, the movable portion 7 constitutes an electrode on one side. Although it is not shown in the drawing, a fixed portion constituting an electrode on the other side which gives rise to electrostatic capacitance between the electrode and the movable portion 7 is provided as a portion of the sensor section 5.

The movable portion 7 shown in FIG. 6A is supported so as to be able to move in the up-and-down direction.

As shown in FIG. 6A, a first metal layer 9 is formed on a lower surface (the surface facing the wiring substrate 2) 8a of the anchor portion 8 by sputtering or the like. Further, the first metal layer 9 is also formed on a lower surface (the surface facing the wiring substrate 2) 6a of the separating layer 6 by sputtering or the like.

As shown in FIG. 6A, the first metal layer 9 provided on the lower surface 8a of the anchor portion 8 and the second metal layer 15 provided on the wiring substrate 2 are joined to each other by eutectic bonding, for example. Then, a wiring portion (not shown) is electrically connected to the second metal layer 15, so that it becomes possible to obtain a detection signal based on a change in electrostatic capacitance of the sensor section 5 through the wiring portion.

Further, as shown in FIGS. 6A and 6B, the first metal layer 9 provided on the lower surface 6a of the separating layer 6 and the second metal layer 15 provided on the wiring substrate 2 are joined to each other by eutectic bonding, for example.

Further, as shown in FIGS. 6A and 6B, the lower surface 6a of the separating layer 6 is cut in the depth direction by etching such as RIE, so that a projecting portion 6b which projects toward the wiring substrate 2 is formed.

Further, as shown in FIGS. 6A and 6B, on the wiring substrate 2, a convex contact portion 13 is provided at a position facing the projecting portion 6b.

In the MEMS sensor 1 shown in FIGS. 6A and 6B, when the projecting portion 6b provided on the lower surface 6a of the separating layer 6 is made to strike the contact portion 13, pressure is applied to the first metal layer 9 and the second metal layer 15, so that the first metal layer 9 and the second metal layer 15 are slightly crushed, and by performing heating in this state, the first metal layer 9 and the second metal layer 15 are joined to each other.

In a structure in which the base materials of the MEMS sensors are joined to each other by a metal layer, since the thickness of the metal layer changes due to crushing or the like of the metal layer by pressurization and heating, the height dimension of a space which is formed between the movable portion and the wiring substrate easily varies. It is presumed that the same problem also arises in the structure of an MEMS sensor according to the invention described in Japanese Unexamined Patent Application Publication No. 2005-236159.

Therefore, it is considered that, as shown in FIGS. 6A and 6B, for example, by providing the projecting portion 6b and the contact portion 13, separately from the metal layers 9 and 15, between the separating portion 6 provided being separated from the sensor section 5 and the wiring substrate 2, and joining the first metal layer 9 and the second metal layer 15 to each other in a state where the surface of the projecting portion 6b is brought into contact with the surface of the contact portion 13, it is possible to maintain an approximately constant height dimension H2 of a space 16 which is formed between the movable portion 7 and the wiring substrate 2.

However, as described above, in the structure in which the projecting portion 6b is formed by cutting the lower surface 6a of the separating layer 6 by wet etching or dry etching, there are problems in that it is difficult to perform control in the depth direction by etching and variation in a depth dimension H1 (refer to FIG. 6B) easily arises.

For this reason, according to each product or even within the same product, variation in the height dimension H2 of the space 16 formed between the movable portion 7 and the wiring substrate 2 becomes large, so that it is difficult to manufacture an MEMS sensor having excellent stability and reliability of detection accuracy.

### SUMMARY OF THE INVENTION

The present invention provides an MEMS sensor in which, particularly, variation in the height dimension of a space which is provided between a first member and a second member can be reduced compared to the related art.

According to an aspect of the invention, there is provided an MEMS sensor including: a first member; a second member disposed facing the first member; and a stopper provided between the opposed surfaces of the first member and the second member, wherein the stopper is configured to include a metal layer formed on the opposed surface of the first member and a contact portion which comes into contact with the metal layer and is provided on the opposed surface of the second member.

In the past, a convex portion has been provided at a position facing a contact portion on the second member side by cutting the surface of the first member by etching. However, in the invention, a stopper structure is provided in which a metal layer is formed at a position facing the contact portion and the metal layer and the contact portion are brought into contact with each other. In this way, variation in the height dimension of a space which is formed the first member and the second member can be reduced compared to the related art. By the above, an MEMS sensor having excellent stability and reliability of detection accuracy can be formed with high productivity and at low cost.

In the above aspect of the invention, it is preferable that at a position of an anchor portion of a sensor section provided in the first member, a first metal layer and a second metal layer be respectively provided on the opposed surface of the first member and the opposed surface of the second member, the first metal layer and the second metal layer be joined to each other, and a third metal layer that is the same film as the first metal layer be formed as the metal layer of the stopper.

In this manner, since the third metal layer that is the same film as the first metal layer is formed, the third metal layer can be simply and appropriately formed, so that it is possible to reduce manufacturing costs.

In the above aspect of the invention, it is preferable that the first metal layer and the third metal layer be formed of Ge and the second metal layer be formed of Al. In this way, the first metal layer and the second metal layer can be joined to each other by eutectic bonding or diffusion bonding, so that it is possible to obtain high joint strength. Further, the third metal layer is formed of Ge, whereby, for example, in a configuration in which a base metal layer made of Ti is formed on the surface of the contact portion, eutectic bonding does not arise between the third metal layer formed of Ge and Ti and diffusion or the like does not also arise between the third metal layer formed of Ge and silicon, so that thermal stability is excellent and a change in the thickness of the third metal layer scarcely occurs. Therefore, it is possible to more effectively reduce variation in the height dimension of a space which is formed between the movable portion and the wiring substrate.

Further, in the above aspect of the invention, it is preferable that on the opposed surface of the second member, a convex portion be provided at a position facing the movable portion of the sensor section, the surface of the convex portion be formed at the same height as the surface of the contact portion, and an allowable space for movement in the height direction of the movable portion be provided between the convex portion and the movable portion. The contact portion and the convex portion can be controlled to be at the same height with high precision by a planarization technique. Then, in the invention, it is possible to more effectively reduce variation in the height dimension of the allowable space. Further, excessive movement of the movable portion toward the second member can be appropriately prevented by formation of the convex portion.

Further, in the above aspect of the invention, it is preferable that the surface of the convex portion and the movable portion have the same electric potential. Even if the movable portion comes into contact with the convex portion, since an electrostatic force is not exercised, sticking based on an electrical factor can be effectively prevented.

Further, in the above aspect of the invention, it is preferable that a fourth metal layer which is electrically connected to the second metal layer be formed to extend to the surface of the convex portion. In this way, the surface of the convex portion and the movable portion can be simply and appropriately made to be at the same electric potential.

Further, in the above aspect of the invention, it is preferable that the fourth metal layer also be provided on the surface of the contact portion and the fourth metal layer formed on the surface of the contact portion and the second metal layer be electrically separated from each other. In this way, it is possible to fit the surface of the contact portion and the surface of the convex portion to the same height, so that variation in the height dimension of the allowable space can be more effectively reduced.

Further, in the above aspect of the invention, it is preferable that the fourth metal layer be a base metal layer for the second metal layer. In this way, it is possible to simply provide the fourth metal layer on the surface of the convex portion or the surface of the contact portion.

Further, in the above aspect of the invention, it is preferable that the base metal layer be formed of Ti. In this way, it is possible to simply and appropriately leave the base metal layer at the necessary place. Further, it is possible to improve adhesion strength between it and the second metal layer.

Further, in the above aspect of the invention, the first member can be preferably applied to a structure in which it is located between the second member and a support substrate and the first member and the support substrate are joined to each other through an insulating layer.

Further, in the above aspect of the invention, it is preferable that the first member be configured to include a sensor section and a separating layer provided being separated from the sensor section, each of the sensor section and the separating layer be joined to the support substrate through an insulating layer, and the stopper be formed between the separating layer and the second member.

As described above, by providing the separating layer separated from the sensor section in the first member, it is possible to appropriately and easily form a stopper at a position away from the sensor section.

Further, in the above aspect of the invention, it is preferable that the separating layer be a frame layer surrounding the sensor section and the stopper and a metal sealing layer surrounding the outer periphery of the sensor section be formed between the frame layer and the second member. In this way, a stopper can be appropriately and easily formed between the frame layer away from the sensor section and the second member and also an MEMS sensor having excellent sealing properties can be formed.

Further, in the above aspect of the invention, the second member can be preferably applied to a form in which it is a wiring substrate which is provided with a conduction pathway.

Further, in the above aspect of the invention, the wiring substrate can be preferably applied to a structure in which it is configured to include a base material, an insulating layer provided on the surface of the base material, and the conduction pathway and the contact portion is formed on the surface of the insulating layer.

According to the invention, an MEMS sensor can be provided which allows variation in the height dimension of a space which is formed between a first member and a second member to be reduced compared to the related art and has excellent stability and reliability of detection accuracy.

### BRIEF DESCRIPTION OF THE DRAWINGS

FIG. 1 is a fragmentary longitudinal cross-sectional view schematically showing an MEMS sensor related to a first embodiment of the invention;

FIG. 2 is a fragmentary longitudinal cross-sectional view schematically showing an MEMS sensor related to a second embodiment of the invention;

FIG. 3 is a plan view of an MEMS sensor (an acceleration sensor) illustrating an embodiment;

FIG. 4 is a fragmentary enlarged longitudinal cross-sectional view of the MEMS sensor cut along line B-B of FIG. 3 and viewed from the arrow direction;

FIG. 5 is a fragmentary enlarged longitudinal cross-sectional view of the MEMS sensor showing a cross-sectional shape different from that in FIG. 4; and

FIG. 6A is a fragmentary longitudinal cross-sectional view of an MEMS sensor in the related art, and FIG. 6B is a fragmentary enlarged longitudinal cross-sectional view of the MEMS sensor.

### DESCRIPTION OF THE PREFERRED EMBODIMENTS

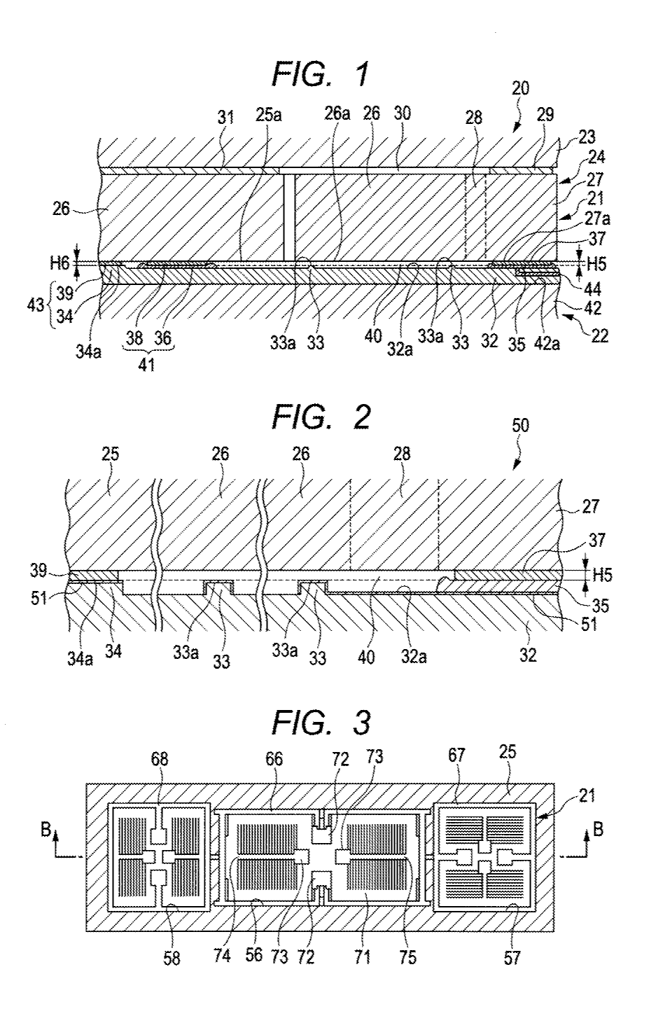

FIG. 1 is a fragmentary enlarged cross-sectional view schematically showing an MEMS sensor in a first embodiment.

An MEMS sensor 20 related to the first embodiment shown in FIG. 1 is constituted in a laminated structure of a wiring substrate (a second member) 22, a support substrate 23, and a functional layer (a first member) 21 which is interposed between the wiring substrate 22 and the support substrate 23. In the embodiment shown in FIG. 1, the support substrate 23 is provided on the upper surface side of the functional layer 21 and the wiring substrate 22 is provided on the lower surface side of the functional layer 21.

Both the functional layer 21 and the support substrate 23 are formed of silicon. The support substrate 23 is formed in a flat plate shape, for example.

As shown in FIG. 1, the functional layer 21 is configured to include a sensor section 24 and a frame layer 25 which is separated from the sensor section 24 and surrounds the sensor portion 24. Further, the sensor section 24 is configured to include an anchor portion 27 and a movable portion 26 which is connected to the anchor portion 27 through a spring portion 28. The movable portion 26 is supported so as to be able to move in the up-and-down direction.

For example, the movable portion 26 constitutes an electrode on one side of an electrostatic capacitance type sensor section. In the sensor section 24, a fixed portion constituting an electrode (not shown) on the other side is provided. The movable portion 26 moves in the up-and-down direction, whereby electrostatic capacitance between the movable portion 26 and the fixed portion changes, and it is possible to detect a change in physical quantity such as acceleration on the basis of a change in electrostatic capacitance.

As shown in FIG. 1, the support substrate 23 and the anchor portion 27 are joined to each other through an insulating layer 29, and the support substrate 23 and the frame layer 25 are joined to each other through an insulating layer 31. As shown in FIG. 1, between the movable portion 26 and the support substrate 23, the insulating layer 29 is not present, but a space 30 is formed. The space 30 is an allowable space for upward (in the drawing) movement of the movable portion 26. The insulating layer 31 is formed in a shape surrounding the sensor section 24 to follow the frame layer 25. It is preferable that the insulating layers 29 and 31 be SiO2. For example, the functional layer 21, the support substrate 23, and the insulating layers 29 and 31 are formed by micro-fabricating SOI substrates.

The wiring substrate 22 is configured to include a silicon base material 42, an insulating layer 32 composed of SiO2 or the like formed on an inner surface 42a of the silicon base material 42, and a wiring portion 44 wired inside the insulating layer 32. As shown in FIG. 1, a leading end of the wiring portion 44 is exposed on a surface 32a of the insulating layer 32 at a position where it is connected to a second metal layer 35 which will be described later. It is possible to obtain a detection signal based on a change in electrostatic capacitance through the wiring portion 44.

In this embodiment, a stopper 43 is formed between the frame layer 25 and the wiring substrate 22. The stopper 43 is constituted by a third metal layer 39 formed on the frame layer 25 side and a contact portion 34 formed on the wiring substrate 22 side, and as shown in FIG. 1, by bringing the third metal layer 39 and the contact portion 34 into contact with each other, control is performed such that the functional layer 21 and the wiring substrate 22 keep a predetermined distance.

As shown in FIG. 1, on the surface (the surface facing the functional layer 21) 32a of the insulating layer 32, a plurality of convex portions 33 is formed at positions facing the movable portion 26. Further, the convex contact portion 34 constituting the stopper 43 is formed at a position facing the frame layer 25. A surface 34a of the contact portion 34 and a surface 33a of each convex portion 33 are formed at approximately the same height.

The surface of the insulating layer 32 formed on the wiring substrate 22 is planarized with use of a planarization technique such as a CMP technique, and in this state, areas other than the convex portions 33 and the contact portion 34 are cut by etching or the like. In this way, as shown in FIG. 1, working can be performed to a state where the convex portions 33 and the contact portion 34 protrude from the surface 32a of the insulating layer 32. However, by the planarization technique described above, it is possible to perform control with high precision such that the surface 33a of each convex portion 33 and the surface 34a of the contact portion 34 are at the same height.

As shown in FIG. 1, on the surface 32a of the insulating layer 32, the second metal layer 35 is formed at a position facing the anchor portion 27. Further, also at a position facing the frame layer 25, a second metal layer 36 is formed. As shown in FIG. 1, for example, the second metal layer 36 is formed further inside (nearer the sensor section 24) than the contact portion 34. Further, the second metal layer 36 is formed in a shape surrounding the sensor section 24 to follow the frame layer 25.

The plurality of second metal layers 35 and 36 are formed at the time of the same process. As the film formation, a sputtering method, a vapor-deposition method, a plating method, or the like can be exemplified. However, particularly, a sputtering method is suitable because variation in film thickness can be more effectively reduced.

As shown in FIG. 1, on a lower surface (the surface facing the wiring substrate 22) 27a of the anchor portion 27, a first metal layer 37 is formed at a position facing the second metal layer 35. Further, on a lower surface (the surface facing the wiring substrate 22) 25a of the frame layer 25, a first metal layer 38 is formed at a position facing the second metal layer 36.

The first metal layer 38 is formed in a shape surrounding the sensor section 24 to follow the frame layer 25.

Further, as shown in FIG. 1, on the lower surface 25a of the frame layer 25, the third metal layer 39 constituting the stopper 43 is formed at a position facing the contact portion 34. The third metal layer 39 is the same film as the first metal layer 38. Accordingly, the plurality of first metal layers 37 and 38 and the third metal layer 39 can be formed at the time of the same process. As the film formation, a sputtering method, a vapor-deposition method, a plating method, or the like can be exemplified. However, particularly, a sputtering method is suitable because variation in film thickness can be more effectively reduced.

In this embodiment, as shown in FIG. 1, the stopper 43 which is composed of the contact portion 34 formed on the wiring substrate 22 side and the third metal layer 39 formed on the frame layer 25 side, which come into contact with each other, is formed between the frame layer 25 and the wiring substrate 22, and at this time, between the movable portion 26 and the wiring substrate 22, an allowable space 40 for downward movement of the movable portion 26 is formed between the surface 33a of each convex portion 33 and a lower surface 26a of the movable portion 26. A height dimension H5 of the allowable space 40 is approximately the same as a film thickness H6 of the third metal layer 39.

Further, in FIG. 1, the first metal layers 37 and 38 and the second metal layers 35 and 36 are joined to each other, so that the functional layer 21 and the wiring substrate 22 are fixed to each other. In a process of joining the wiring substrate 22 and the functional layer 21 to each other, when the contact portion 34 on the wiring substrate 22 side and the third metal layer 39 on the functional layer 21 side, which constitute the stopper 43, have been made to strike each other, a state is created where the first metal layers 37 and 38 and the second metal layers 35 and 36 are slightly crushed under pressure. By carrying out a heating treatment in the state, the first metal layers 37 and 38 and the second metal layers 35 and 36 can be appropriately and easily joined to each other. As the joining, eutectic bonding, diffusion bonding, or the like can be exemplified.

In this embodiment, the first metal layer 38 and the second metal layer 36 provided between the frame layer 25 and the wiring substrate 22 constitute a metal sealing layer 41 surrounds the sensor section 24.

The third metal layer 39 and the contact portion 34 which constitute the stopper 43 are not joined to each other in a state where the third metal layer 39 and the contact portion 34 come into contact with each other, as shown in FIG. 1. Therefore, also in a pressurizing and heating process for the joining of the first metal layers 37 and 38 and the second metal layers 35 and 36 to each other, a change in film thickness of the third metal layer 39 can be effectively suppressed. Therefore, as shown in FIG. 1, the film thickness H6 of the third metal layer 39 in a state where it is brought into contact with the contact portion 34 is maintained at approximately the same film thickness as that at the time of film formation.

Further, the third metal layer 39 is formed by sputtering or the like, so that variation in film thickness can be greatly reduced within each product and between the respective products. Accordingly, variation in the height dimension H5 of the allowable space 40 formed between the movable portion 26 and the convex portion 33 can be reduced compared to the related art.

Further, in this embodiment, the third metal layer 39 is the same film as the first metal layer 37 and the third metal layer 39 can be formed at the time of the same process as that of the first metal layer 37, and therefore, production efficiency can be improved and the production cost can be reduced.

In the embodiment shown in FIG. 1, the plurality of convex portions 33 is formed at the area of the wiring substrate 22 which faces the movable portion 26. Accordingly, excessive downward movement of the movable portion 26 can be suppressed.

Further, the convex portions 33 need not be formed at the positions of the wiring substrate 22 which face the movable portion 26. However, in order to more effectively reduce variation in the height dimension H5 of the allowable space 40 for the movable portion 26, it is preferable that the convex portions 33 be provided.

In a case where the convex portions 33 are not formed at positions facing the movable portion 26, a cutout depth formed on the surface 32a of the insulating layer 32 of the wiring substrate 22 is also added to the height dimension of the allowable space, whereby variation in cutout depth leads to variation in the height dimension of the allowable space. In contrast, in the embodiment of FIG. 1, as described above, since the surfaces 33a of the convex portions 33 and the surface 34a of the contact portion 34 can be adjusted to the same height with high precision by a planarization treatment, the height dimension H5 of the allowable space 40 can be controlled by the film thickness H6 of the third metal layer 39. Further, in this embodiment, since the third metal layer 39 is formed by sputtering or the like at the time of the same process as that of the first metal layers 37 and 38, variation in the film thickness of the third metal layer 39 can be greatly reduced, and therefore, variation in the height dimension H5 of the allowable space 40 can be more effectively reduced.

In the embodiment shown in FIG. 1, the frame layer 25 separated from the sensor section 24 is provided in the functional layer 21. Then, the sensor section 24 is surrounded by the frame layer 25, the support substrate 23, the wiring substrate 22, the metal sealing layer 41, and the insulating layer 31, so that it is possible to obtain the MEMS sensor 20 having excellent sealing properties.

Further, a configuration in which the frame layer 25 is not formed is also possible. However, as shown in FIG. 1, by taking a configuration in which the frame layer 25 is provided, the stopper 43 can be appropriately and easily provided between the frame layer 25 away from the sensor section 24 and the wiring substrate 22.

In addition, the stopper 43 need not be formed so as to surround the sensor section 24, unlike the metal sealing layer 41 (of course, it may also be formed so as to surround the sensor section 24). However, it is preferable that the stoppers 43 be provided at plural places. For example, when orthogonal straight lines passing the center of the substrate in a plane are set to be X1-X2 and Y1-Y2, providing the stoppers 43 at the respective places further on the X1 side, the X2 side, the Y1 side, and the Y2 side than the center of the substrate allows the wiring substrate 22 and the functional layer 21 to be joined to each other in a parallel fashion with high precision without making the wiring substrate 22 and the functional layer 21 joined to each other in an inclined fashion.

In this embodiment, as the combination of materials of the first metal layers 37 and 38 and the second metal layers 35 and 36, there is aluminum-germanium, aluminum-zinc, gold-silicon, gold-indium, gold-germanium, gold-tin, or the like.

Accordingly, the first metal layers 37 and 38 and the second metal layers 35 and 36 can be joined to each other by eutectic bonding or diffusion bonding, so that it is possible to obtain high joint strength.

Further, in this embodiment, it is preferable that the first metal layers 37 and 38 and the third metal layer 39 be formed of germanium (Ge) and the second metal layers 35 and 36 be formed of aluminum (Al). In this way, for example, diffusion or the like does not arise between the third metal layer 39 and the frame layer 25 (the functional layer 21) formed of silicon, thermal stability is excellent, and a change in the thickness of the third metal layer 39 scarcely arises. Therefore, it is possible to more effectively reduce variation in the height dimension H5 of the allowable space 40.

FIG. 2 is a fragmentary enlarged longitudinal cross-sectional view schematically showing an MEMS sensor 50 in a second embodiment. In FIG. 2, the same portion as that in FIG. 1 is denoted by the same symbol and explanation thereof is omitted.

In the embodiment shown in FIG. 2, a base metal layer (a fourth metal layer) 51 of the second metal layer 35 is provided, and the base metal layer 51 is formed to extend from the surface 32a of the insulating layer 32 to the surface 33a of the convex portion 33. The surfaces 33a of the plurality of convex portions 33 are electrically connected to each other by the base metal layer 51.

Further, the base metal layer 51 is also formed on the surface 34a of the contact portion 34. However, the base metal layer 51 formed on the surface 34a of the contact portion 34 is not electrically connected to the base metal layer 51 formed on the surface 33a of the convex portion 33 and the second metal layer 35.

The base metal layer 51 is made of Ti, for example, and after the base metal layer 51 made of Ti is formed on the entire surface of the insulating layer 32, an unnecessary base metal layer 51 is removed, and the base metal layers 51 respectively remain on an area from the surface 33a of each convex portion 33 to below the second metal layer 35 and on the surface 34a of the contact portion 34.

The base metal layer 51 is for improving the adhesion strength of the second metal layer 35, and if particularly the second metal layer 35 is made of aluminum (Al), it is possible to more effectively improve the adhesion strength.

The second metal layer 35 is electrically connected to the movable portion 26 through the first metal layer 37, the anchor portion 27, and the spring portion 28, and further, in the embodiment of FIG. 2, by forming the base metal layer 51 electrically connected to the second metal layer 35 so as to extend to the surface 33a of each convex portion 33, an open circuit is formed between the movable portion 26 and the surface 33a of the convex portion 33 and the movable portion 26 and the surface 33a of the convex portion 33 have the same electric potential.

Therefore, even if the movable portion 26 moves downward, thereby coming into contact with the surface of the convex portion 33, an electrostatic force is not exercised, so that sticking based on an electrical factor can be effectively prevented. Further, in this embodiment, the base metal layer 51 is also provided on the surface 34a of the contact portion 34, whereby it is possible to fit the surface (equivalent to the surface of the base metal layer 51) of the contact portion 34 and the surface (equivalent to the surface of the base metal layer 51) of the convex portion 33 to the same height. Therefore, the height dimension H5 of the allowable space 40 can be controlled by the film thickness H6 of the third metal layer 39 and variation in the height dimension H5 can be effectively reduced.

In place of the base metal layer 51, a separate fourth metal layer may also be formed to extend from an electrical connection position of the second metal layer 35 to the surface 33a of the convex portion 33. However, by using the base metal layer 51 of the second metal layer 35, it is possible to simply and properly perform control such that the movable portion 26 and the surface 33a of the convex portion 33 are at the same electric potential, and it is easy to fit the surface of the contact portion 34 and the surface of the convex portion 33 to the same height.

Further, if Ti is used as the base metal layer 51, eutectic bonding does not arise between the third metal layer 39 formed of Ge and the base metal layer 51 formed on the surface of the contact portion 34 and occurrence of a change in the film thickness of the third metal layer 39 can be suppressed. Therefore, it is possible to more effectively reduce variation in the height dimension H5 of the allowable space 40 for the movable portion 26.

The structures of the MEMS sensors related to the embodiments shown in FIGS. 1 and 2 can be applied to, for example, an MEMS sensor shown in FIG. 3.

FIG. 3 is a plan view of an MEMS sensor (an acceleration sensor) in this embodiment. In addition, a plan view of FIG. 3 is shown seeing through the support substrate 23.

The MEMS sensor shown in FIG. 3 has, for example, a rectangular shape having a long side in the X direction and a short side in the Y direction.

As shown in FIG. 3, in the functional layer 21, the frame layer 25 is formed at a peripheral area, and the inside of the frame layer 25 becomes a formation area of the sensor section. In FIG. 3, the frame layer 25 is shown by oblique lines.

As shown in FIG. 3, in the functional layer 21, a first hole 56, a second hole 57, and a third hole 58, which define the outer shapes of the sensor sections, are formed inside the frame layer 25, and the respective holes 56, 57, and 58 penetrate the frame layer 25 in the thickness direction.

As shown in FIG. 3, the insides of the respective holes 56, 57, and 58 are sensor sections 66, 67, and 68.

In the MEMS sensor shown in FIG. 3, for example, the sensor section 66 provided in the middle detects acceleration in the Z direction (the height direction), the sensor section 67 provided on the right side in the drawing detects acceleration in the Y1-Y2 direction, and the sensor section 68 provided on the left side in the drawing detects acceleration in the X1-X2 direction.

As shown in FIG. 3, a movable portion 71 provided in the sensor section 66 is connected to anchor portions 72 and 72 through a spring portion and supported so as to be able to move in the up-and-down direction. On the other hand, fixed portions 74 and 75 extend from anchor portions 73 and 73, and if the movable portion 71 moves up and down, a change in electrostatic capacitance occurs between each of toothcomb-shaped fixed electrodes provided at the fixed portions 74 and 75 and each of toothcomb-shaped movable electrodes provided at the movable portion 71.

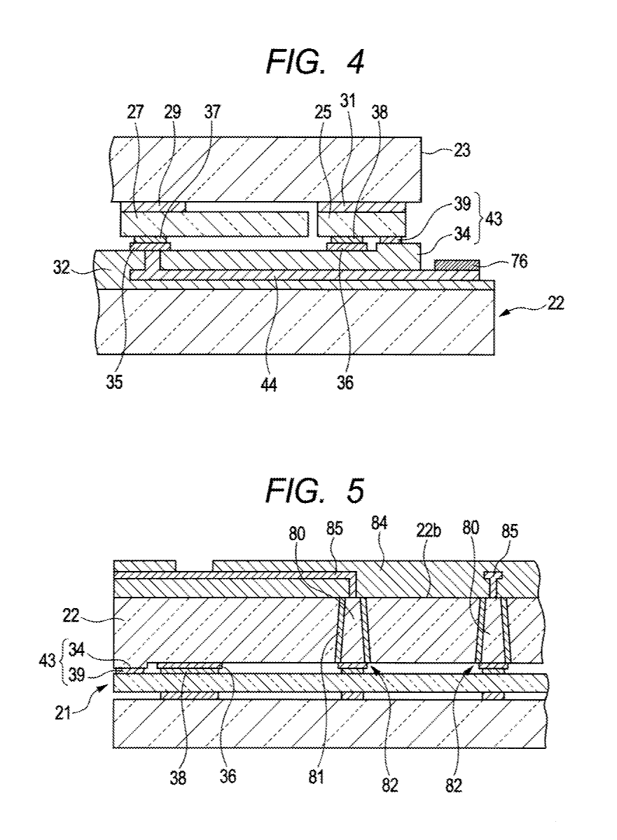

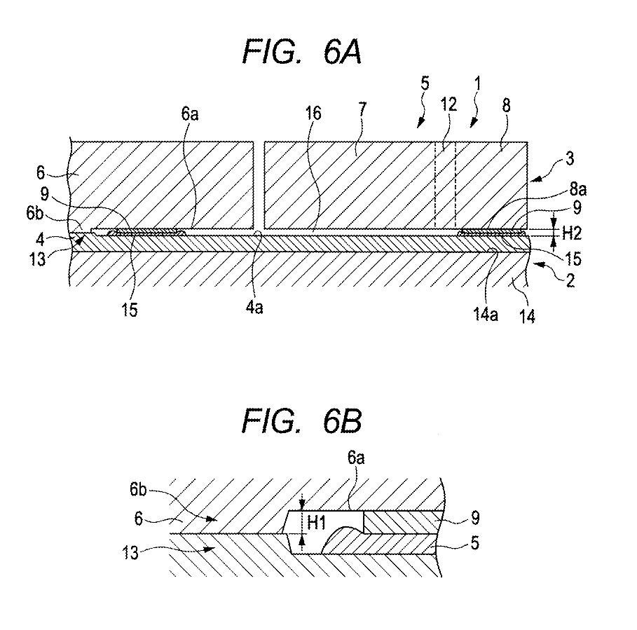

FIG. 4 is a fragmentary enlarged longitudinal cross-sectional view when the MEMS sensor shown in FIG. 3 is cut along line B-B and viewed from an arrow direction.

As shown in FIG. 4, the stopper 43 which is composed of the third metal layer 39 that is the same film as the first metal layers 37 and 38 and the contact portion 34 which come into contact with each other is formed between the frame layer 25 and the wiring substrate 22.

In addition, as shown in FIG. 4, the wiring portion 44 connected to the second metal layer 35 and wired inside the insulating layer 32 is led out in an external direction further than the support substrate 23, for example, and is conductively connected to an external connection pad 76.

Further, it is also possible to take a cross-sectional structure shown in FIG. 5.

In an embodiment shown in FIG. 5, penetration wiring layers 80 penetrating the wiring substrate 22 are provided. Each penetration wiring layer 80 and the wiring substrate 22 are insulated from each other by an insulating layer 81. As shown in FIG. 5, each penetration wiring layer 80 and the anchor portion are joined to each other through a metal layer 82 which is composed of the first metal layer 37 and the second metal layer 35 explained in FIG. 4. Further, an insulating layer 84 covers an opposite surface 22b to the surface of the wiring substrate 22 which faces the functional layer 21, and as shown in FIG. 5, a wiring portion 85 contacting the penetration wiring layers 80 is formed inside the insulating layer 84. A portion of the wiring portion 85 is exposed from the surface of the insulating layer 84, thereby constituting an external connection pad.

Further, also in the embodiment shown in FIG. 5, the stopper 43 which is composed of the third metal layer 39 that is the same film as the first metal layers 37 and 38 and the contact portion 34 which come into contact with each other is formed between the frame layer 25 and the wiring substrate 22.

In addition, in this embodiment, the wiring substrate may also be IC.

Further, the MEMS sensor in this embodiment is preferably applied to a physical quantity sensor such as an acceleration sensor, a gyro sensor, or a shock sensor. Further, a detection principle of the sensor section is also not limited to an electrostatic capacitance type.

Further, in the embodiments described above, as the second member, the wiring substrate 22 is exemplified. However, instead of the wiring substrate 22, a simple substrate for sealing can also be applied.

Further, the configuration of the first member in this embodiment may also be a member other than the functional layer 21 described above. For example, it can also be applied to an MEMS sensor without the movable portion 26

It should be understood by those skilled in the art that various modifications, combinations, sub-combinations and alterations may occur depending on design requirements and other factors insofar as they are within the scope of the appended claims of the equivalents thereof.

What is claimed is:

1. An MEMS sensor comprising:
a first member;
a second member disposed facing the first member; and
a stopper provided between the opposed surfaces of the first member and the second member,
wherein the stopper is configured to include a metal layer formed on the opposed surface of the first member and a contact portion which comes into contact with the metal layer and is provided on the opposed surface of the second member.

2. The MEMS sensor according to claim 1, wherein at a position of an anchor portion of a sensor section provided in the first member, a first metal layer and a second metal layer are respectively provided on the opposed surface of the first member and the opposed surface of the second member,
the first metal layer and the second metal layer are joined to each other, and
a third metal layer that is the same film as the first metal layer is formed as the metal layer of the stopper.

3. The MEMS sensor according to claim 2, wherein the first metal layer and the third metal layer are formed of Ge, and the second metal layer is formed of Al.

4. The MEMS sensor according to claim 2, wherein on the opposed surface of the second member, a convex portion is provided at a position facing the movable portion of the sensor section, the surface of the convex portion is formed at the same height as the surface of the contact portion, and an allowable space for movement in the height direction of the movable portion is provided between the convex portion and the movable portion.

5. The MEMS sensor according to claim 4, wherein the surface of the convex portion and the movable portion have the same electric potential.

6. The MEMS sensor according to claim 5, wherein a fourth metal layer which is electrically connected to the second metal layer is formed to extend to the surface of the convex portion.

7. The MEMS sensor according to claim 6, wherein the fourth metal layer is also provided on the surface of the contact portion, and the fourth metal layer formed on the surface of the contact portion and the second metal layer are electrically separated from each other.

8. The MEMS sensor according to claim 6, wherein the fourth metal layer is a base metal layer for the second metal layer.

9. The MEMS sensor according to claim 8, wherein the base metal layer is formed of Ti.

10. The MEMS sensor according to claim 1, wherein the first member is located between the second member and a support substrate, and the first member and the support substrate are joined to each other through an insulating layer.

11. The MEMS sensor according to claim 10, wherein the first member is configured to include a sensor section and a separating layer provided being separated from the sensor section, and each of the sensor section and the separating layer is joined to the support substrate through an insulating layer, and
the stopper is formed between the separating layer and the second member.

12. The MEMS sensor according to claim 11, wherein the separating layer is a frame layer surrounding the sensor section, and the stopper and a metal sealing layer surrounding the outer periphery of the sensor section are formed between the frame layer and the second member.

13. The MEMS sensor according to claim 1, wherein the second member is a wiring substrate which is provided with a conduction pathway.

14. The MEMS sensor according to claim 13, wherein the wiring substrate is configured to include a base material, an insulating layer provided on the surface of the base material, and the conduction pathway, and the contact portion is formed on the surface of the insulating layer.
